(19) United States
(12) Patent Application Publication
(10) Pub. No.: US 2025/0220971 A1
(43) Pub. Date: Jul. 3, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tzu-Ging LIN, Kaohsiung (TW); Jih-Jse LIN, New Taipei City (TW); Yi-Chun CHEN, Hsinchu (TW); Chieh-Ning FENG, Taichung (TW); Chih-Chang HUNG, Hsinchu (TW)

(21) Appl. No.: 18/646,964

(22) Filed: Apr. 26, 2024

Related U.S. Application Data
(60) Provisional application No. 63/615,219, filed on Dec. 27, 2023.

(51) Int. Cl. H01L 29/423; H01L 21/8234; H01L 27/088; H01L 29/06; H01L 29/08; H01L 29/66; H01L 29/775; H01L 29/78; H01L 29/786

(52) U.S. Cl. CPC H10D 30/6735; H10D 30/014; H10D 30/43; H10D 30/6757; H10D 62/115; H10D 62/121; H10D 62/151; H10D 64/017; H10D 84/0128; H10D 84/0135; H10D 84/038; H10D 30/024; H10D 30/62; H10D 84/0158; H10D 84/834

(57) ABSTRACT

Embodiments of the present disclosure provide an etch process for forming high aspect ratio trenches, such as CPODE/CMODE trenches, without damaging adjacent structures, such as the epitaxial source/drain features.

### CROSS-REFERENCE TO RELATED APPLICATIONS

This application claims priority to United States Provisional Patent Application Ser. No. 63/615,219, filed Dec. 27, 2023, which is incorporated by reference in its entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary.

Device layout may adopt polycrystalline silicon (poly) segments formed as diffusion edge (PODE) or continuous poly on diffusion edge (COPED) to avoid leakage between neighboring devices. A PODE pattern or a CPODE pattern is used to form the poly segments. As device dimension scales down, such as gate pitch, design schemes, such as PODE and CPODE schemes, may face difficulties to provide the level of device density, cell isolation, and device performance required for aggressively scaled circuits and devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor substrate according to embodiments of the present disclosure.

FIGS. 2A-2B to 11A-11B schematically illustrate various stages of manufacturing a semiconductor device according to embodiments of the present disclosure.

FIGS. 12A-12D are partial sectional views of a semiconductor device at various stages.

FIG. 12E is a schematic cross-sectional view of an example device according to the present disclosure.

FIG. 13 is a flow chart of a method for manufacturing of a semiconductor substrate according to embodiments of the present disclosure.

FIG. 14A is a schematic layout view of a semiconductor device according to the present disclosure.

FIG. 14B is a schematic cross sectional view of the semiconductor device of FIG. 14A.

FIG. 14C is a schematic layout view of a semiconductor device according to the present disclosure.

FIG. 14D is a schematic cross sectional view of the semiconductor device of FIG. 14C.

FIG. 14E is a schematic layout view of a semiconductor device according to the present disclosure.

FIG. 14F is a schematic cross sectional view of the semiconductor device of FIG. 14E.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of present disclosure relates to forming isolation structures in gate structures to prevent current leakage through source/drain regions (EPI), transistors, and silicon substrate. The isolation structures may be formed in the gate structure prior to or after the replacement gate sequence. Continuous polysilicon on diffusion edge (CPODE) processes, which involves silicon gate etch processes, may be performed prior to the replacement gate sequence. Continuous metal on diffusion edge (CMODE) processes, which involves metal gate etch processes, may be performed after the replacement gate sequence.

Embodiments of the present disclosure relate to method for forming CPODE or CMODE openings within small epitiaxal spacings without damaging the epitaxial regions. As integrated circuit scales down, epitaxial critical dimension (EPI CD), which refers to spacings between epitxials regions, becomes smaller and smaller. Small EPI CD makes it challenging to etch the CPODE or CMODE trenches without damaging the adjacent epitaxial feature. Embodiments of the present disclosure provide an etch process for forming high aspect ratio trenches, such as CPODE/CMODE trenches, without damaging adjacent structures, such as the epitaxial source/drain features.

Conventionally, CPODE/CMODE opening for very small EPI CD may be achieved using cyclic steps for passivation, breakthrough, and semiconductor etch. However, such cyclic schememe takes a long time with high cost of manufacturing. Embodiments of the present disclosure provide a tunable etch scheme near epitaxial regions to achieve maximium economic benefits. In some embodiments, the semiconductor etch process may be performed by continuously etching to a first depth, depositing a passivation layer with improved etch resistivity, perform a passivation break through process, and then etch semiconductor material to a desired depth. The first depth may be tuned according to process design. In some embodiments, the first depth is tuned to where a minimum EPI CD is desired.

In advanced nodes with high transistor density, an overlay shift may be applied when forming a CPODE/CMODE pattern in a mask layer. to prevent photoresist peeling during fabrication. The etch process according to the present disclosure may be used to correct the overlay shift in the CPODE/CMODE openings in the semiconductor fins, thereby, improving product quality and performance.

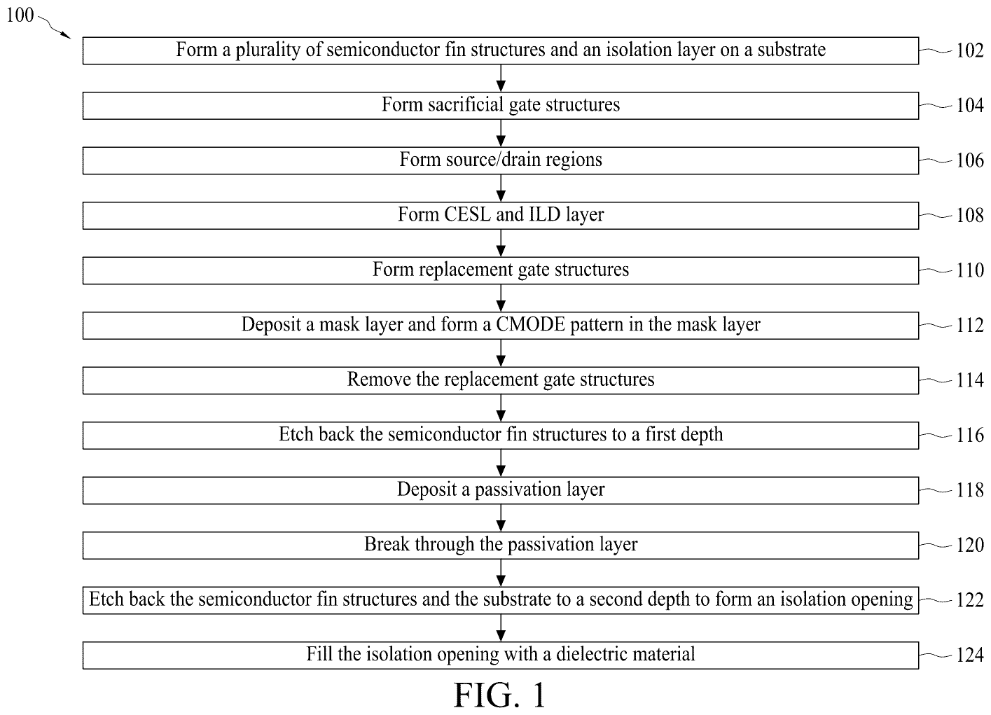

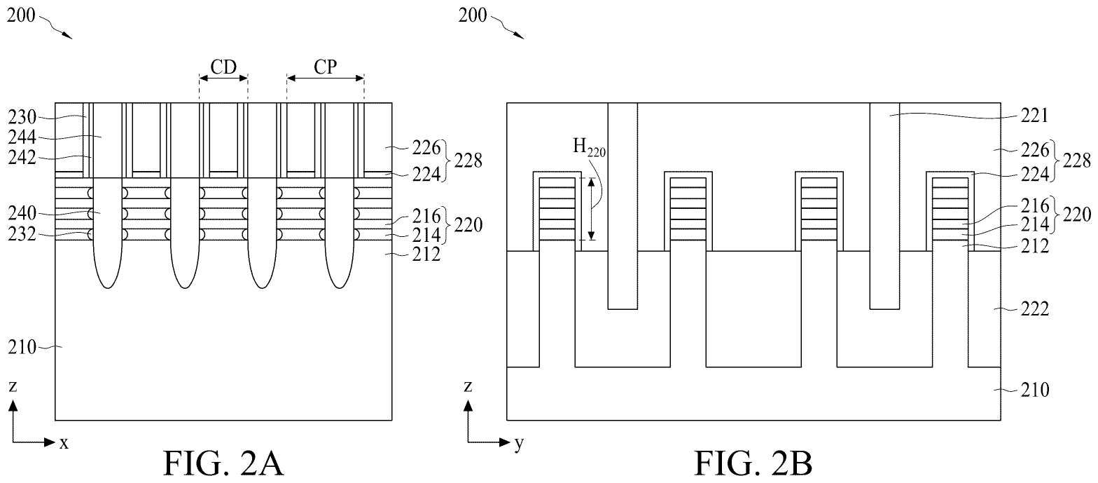

FIG. 1 is a flow chart of a method 100 for manufacturing of a semiconductor substrate according to embodiments of the present disclosure. Particularly, the method 100 relates to forming a semiconductor device with CMODE isolation structures. FIGS. 2A-2B to 11A-11B schematically illustrate various stages of manufacturing a semiconductor device 200 according to embodiments of the present disclosure using the method 100.

The method 100 begins at operation 102 where a plurality of semiconductor fins 220 are formed over a substrate 210, as shown in FIGS. 2A-2B. FIG. 2A is a cross-sectional view of the semiconductor device 200 along the x-direction. FIG. 2B is a schematic cross-sectional view of the semiconductor device 200 along the y-direction.

The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure for enhancement.

The semiconductor fins 220 are formed on and in the substrate 210. Each of the semiconductor fins 220 includes a well portion 212 formed from the semiconductor substrate 210 and a semiconductor stack including alternatively stacked scarificial layers 214 and semiconductor channel layers 216. The semiconductor fins 220 may be formed by patterning a hard mask deposited on the semiconductor stack and one or more etching processes. The semiconductor fins 220 are formed along the x-direction. The semiconductor stack of the semiconductor fins 220 have a stack height H₂₂₀. In some embodiments, the stack height H₂₂₀ is in a range between about 20 nm and 50 nm.

An isolation layer 222 is then formed in the trenches between the semiconductor fins 220. The isolation layer 222 may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the semiconductor fins 220 by a suitable deposition process, such as atomic layer deposition (ALD), and then recess etched using a suitable anisotropic etching process to expose the channel portions 218 of the semiconductor fins 220.

In operation 104, sacrificial gate structures 228 and spacer layers 230 are then formed over the semiconductor fins 220, as shown in FIGS. 2A-2B. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. A patterning operation is the performed over the sacrificial gate dielectric layer 224 and the sacrificial gate electrode layer 226 to form the sacrificial gate structures 228, which cover portions of the semiconductor fins 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SiN, SiON, SiOCN or SiCN and combinations thereof. In some embodiments, the gate sidewall spacers 230 may be formed from two or more layers of dielectric materials.

After formation of the gate sidewall spacers 230, the semiconductor fins 220 are etched back to form source/drain recesses on sides of the sacrificial gate structures 228. Ends of the scarificial layers 214 and semiconductor channel layers 216 are exposed to the source/drain recesses. In some embodiments, the sacrificial layers 214 are semiconductor layers. In other embodiments, the sacrificial layers 214 are oxide layers. The scarificial layers 214 are first etched horizontally along the X direction to form cavities between the semiconductor channel layers 216. In some embodiments, the scarificial layers 214 can be selectively etched by using wet etchant or dry etchant such as, but not limited to, ammonium hydroxide (NH₄OH), tetramethylammonium hydroxide (TMAH), ethylenediamine pyrocatechol (EDP), or potassium hydroxide (KOH) solutions, or halogen based gas, such as Cl2, NF3, or HF and NH3. In some embodiments, the amount of etching of the scarificial layer 214 is in a range between about 2 nm and about 10 nm along the X direction. After forming cavities in the scarificial layers 214, inner spacers 232 can be formed in the cavities by conformally deposit and then partially remove an insulating layer. The insulating layer can be formed by ALD or any other suitable method. In some embodiments, the insulating layer may include one of silicon nitride (SiN) and silicon oxide (SiO₂) and have a thickness in a range from about 0.5 nm to about 3.0 nm. The subsequent etch process removes most of the insulating layer except inside the cavities, resulting in the inner spacers 232.

The sacrificial gate structures 228 have a gate pitch GP. In some embodiments, the gate pitch GP is less than 50 nm, for example, the gate pitch is between about 20 nm and about 30 nm.

In operation 106, source/drain regions 240 are formed in the sourced/drain recesses, as shown in FIGS. 2A-2B. The source/drain regions 240 may be formed by an epitaxial growth method using CVD, ALD or molecular beam epitaxy (MBE) from the semiconductor channel layers 216 and well portions 212 of the fin structures 220. The source/drain regions 240 may include one or more layers of Si, SiP, SiC and SiCP for NFET or Si, SiGe, Ge for a PFET. For the PFET, p-type dopants, such as boron (B), may also be included in the source/drain regions 240.

As shown in FIG. 2A, the spacing between the source/drain regions 240 across each gate structures 228 along the x-direction may be referred to as epitaxial CD. In some embodiments, the eptixial CD may be in a range between about 10 nm and about 20 nm.

In operation 108, a contact etch stop layer (CESL) 242 and an interlayer dielectric (ILD) layer 244 are formed over the exposed surfaces, as shown in FIGS. 2A-2B. The CESL 242 is formed on the epitaxial source/drain regions 240 and the gate sidewall spacers 230. The CESL 242 may include Si₃N₄, SiON, SiCN or any other suitable material, and may be formed by CVD, PVD, or ALD. The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In some embodiments, a cut poly gate (CPO) process may be performed to remove a portion of the sacrificial gate structure 228 to form cut features, such as trenches, and subsequently fill the cut features with a dielectric material to form gate isolation features 221 in the sacrificial gate structures 228.

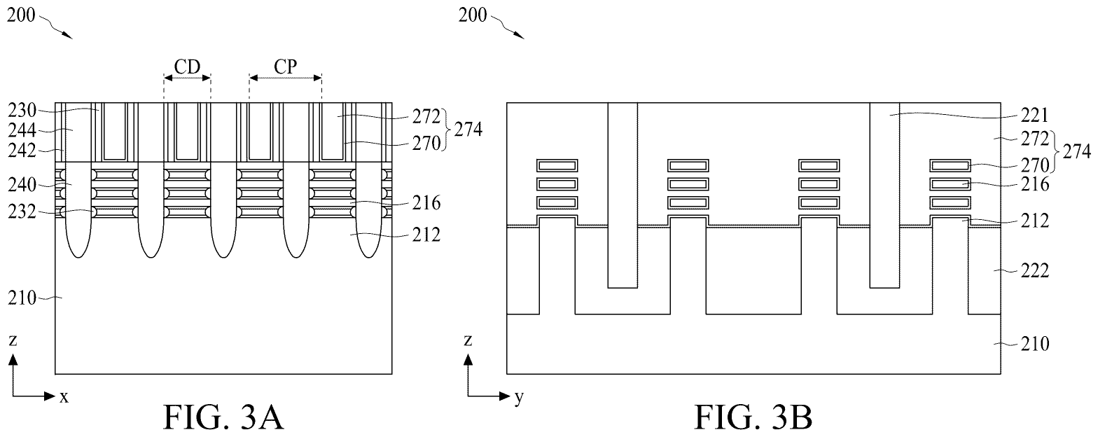

In operation 110, replacement gate process is performed as shown in FIGS. 3A-3B. FIG. 3A is a cross-sectional view of the semiconductor device 200 along the x-direction. FIG. 3B is a schematic cross-sectional view of the semiconductor device 200 along the y-direction.

The sacrificial gate structures 228 are first removed. Particularly, the sacrificial gate electrode layer 226 and the sacrificial gate dielectric layer 224 are removed sequentially to expose the semiconductor fins 220, i.e. the semiconductor channel layers 216 and the well portions 212 of the semiconductor fins 220. The replacement gate structures 274 are then formed around the semiconductor channel layers 216 and the well portions 212. A gate dielectric layer 270 is formed on the semiconductor channel layers 216 and the well portions 212. A gate electrode layer 272 is formed on the gate dielectric layer 270. The gate dielectric layer 270 and the gate electrode layer 272 may be referred to as a replacement gate structure 274.

The gate dielectric layer 270 may be formed by CVD, ALD or any suitable method. In one embodiment, the gate dielectric layer 270 is formed using a highly conformal deposition process such as ALD. The gate dielectric layer 270 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂−Al₂O₃) alloy, other suitable high-k dielectric materials, and/or combinations thereof.

The gate electrode layer 272 is formed on the gate dielectric layer 270. The gate electrode layer 272 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 272 may be formed by CVD, ALD, electro-plating, or other suitable method.

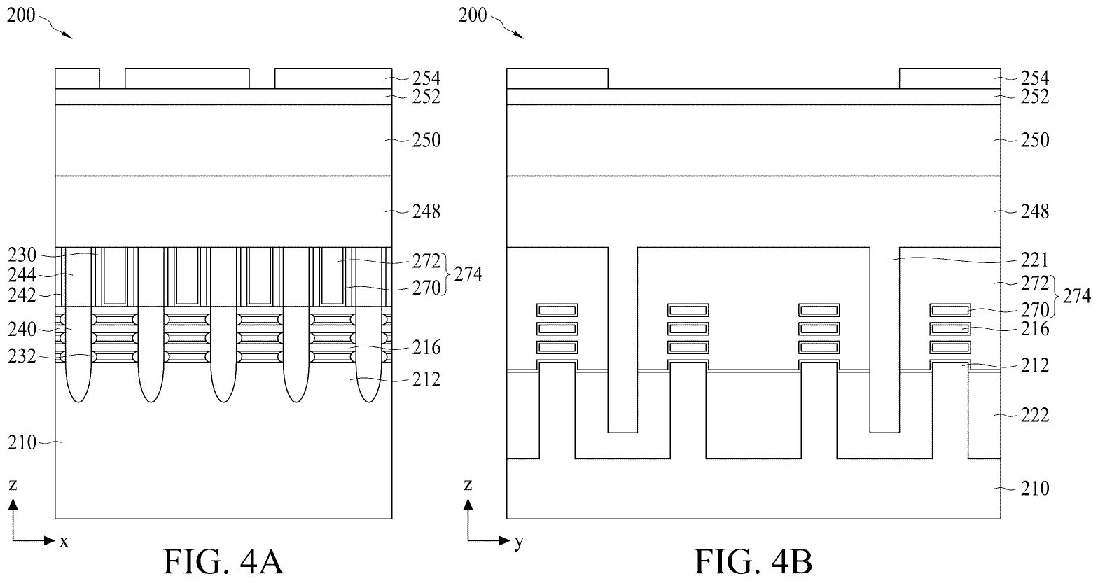

In operation 112, a mask layer 248 is deposited on the semiconductor device 200, as shown in FIGS. 4A-4B. FIG. 4A is a cross-sectional view of the semiconductor device 200 along the x-direction. FIG. 4B is a schematic cross-sectional view of the semiconductor device 200 along the y-direction.

The mask layer 248 may include one or more dielectric layer. The mask layer 248 may be deposited over the replacement gate structures 274, the gate sidewall spacers 230, the CESL 242, and ILD layer 244. In some examples, the one or more mask layers may include or be silicon nitride, silicon oxynitride, silicon carbide, silicon carbon nitride, the like, or a combination thereof, and may be deposited by CVD, PVD, ALD, or another deposition technique. In some embodiments, the mask layer 248 may be a film with compressed stress because openings formed in the compressed stress film may not have gaps. In some embodiments, the mask layer 248 may be a silicon nitride having a thickness in a range between about 650 angstroms and 850 angstroms, for example between about 730 angstroms and about 750 angstroms.

A photolithographic process is performed to form a CMODE pattern in a photoresist layer, as shown in FIGS. 4A-4B. In some embodiments, a tri-layer photoresist stack including a bottom layer 250, a back anti-reflection coating (BARC) 252, and a photo resist (PR) layer 254 are deposited. A lithographic process is performed to form a CMODE pattern.

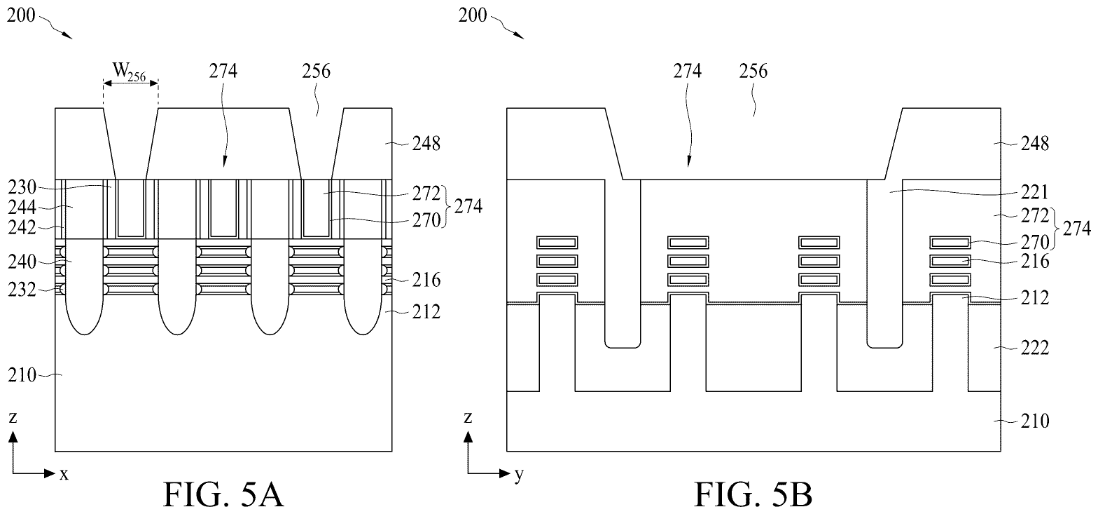

In some embodiments, the CMODE pattern is transferred to the mask layer 248, as shown in FIGS. 5A-5B. FIG. 5A is a cross-sectional view of the semiconductor device 200 along the x-direction. FIG. 5B is a schematic cross-sectional view of the semiconductor device 200 along the y-direction. The CMODE pattern may include one or more elongated openings 256 in alignment with the replacement gate structures 274. The elongated openings 256 may be arranged in a pattern to achieve isolation across semiconductor fins 220. As shown in FIGS. 5A-5B, the enlongated opening 256 exposes a segment of the replacement gate structure 274. In some embodiments, the elongated opening 256 may have a width W₂₅₆ along the x-direction. In some embodiments, the width W₂₅₆ is at least about 50% of the gate pitch GP, for example, the width W₂₅₆ is in a range between about 15 nm and about 30 nm.

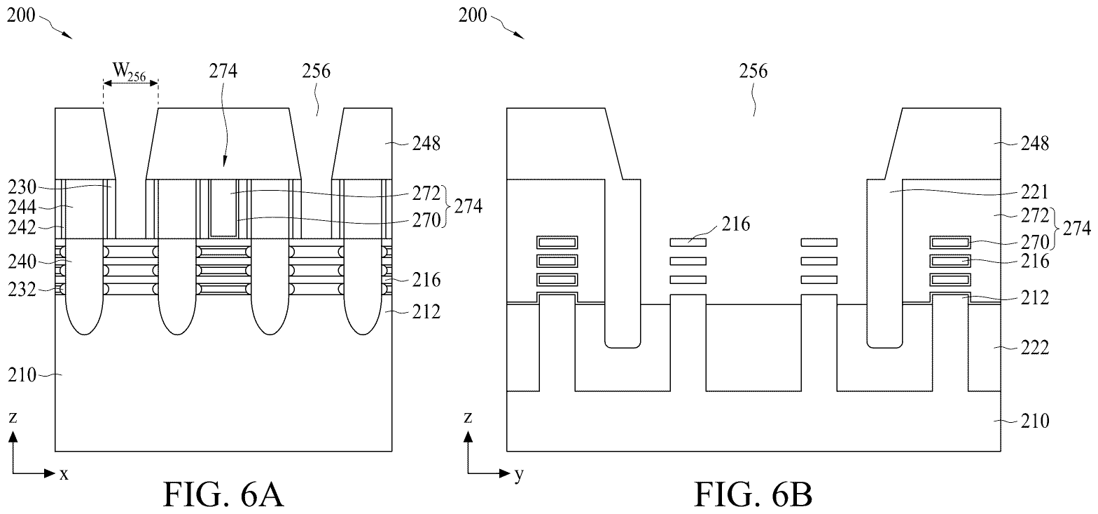

In operation 114, an etch process is performed to selectively remove a portion of the replacement gate structures 274 through the enlongated opening 256 in the mask layer 248, as shown in FIGS. 6A-6B. FIG. 6A is a cross-sectional view of the semiconductor device 200 along the x-direction. FIG. 6B is a schematic cross-sectional view of the semiconductor device 200 along the y-direction.

In some embodiments, an etch chemistry is selective to the metal gate structure layer(s) to be etched, while minimizing etching of the surrounding dielectric layers, such as the isolation layer 222. the sidewall spacers 230, the CESL 242, and the ILD layer 244. In some embodiments, the replacement gate structures 274 may be removed using chlorine containing gases, such as SiCl₄, BCl₃, Cl₂, CHCl₃, CCl₄, and/or BCl₃, bromine-containing gas, such as HBr and/or CHBr₃, iodine-containing gas, other suitable gases and/or plasmas, and/or combinations thereof. In some embodiments, the gate dielectric layer 270 may be removed by any suitable etching process, such as plasma dry etching and/or wet etching. As shown in FIG. 6B, under the elongated opening 256 in the mask layer 248, the replacement gate structures 274 may be substantially removed exposing the gate spacers 230, the semiconductor channel layers 216, and the well portion 212.

In operations 116, 118, 120, and 122, semiconductor materials exposed by the elongated openings 256 are removed forming isolation openings. Particularly, the operations 116, 118, 120, 122 may be used to form trenches in the semiconductor materials without harming the epitaxial source/drain regions 240 having small spacings. In some embodiments, the operations 116, 118, 120, and 122 may be performed in the same process chamber, such as an ALD chamber, to achieve lower cost of manufacturing.

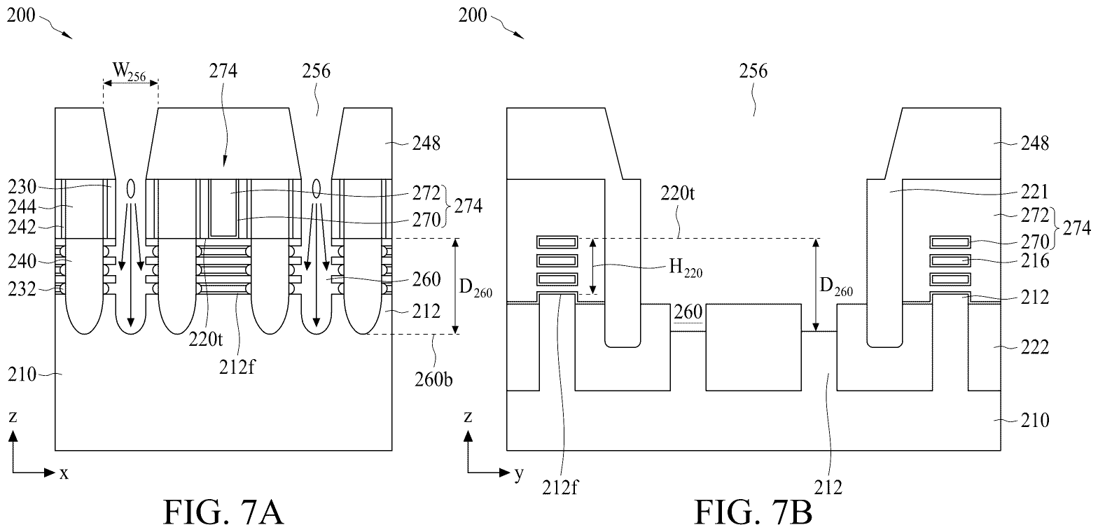

In operation 116, a suitable etch process is performed to remove the semiconductor material, such as the semiconductor channel layers 216 and the well portion 212 of the substrate 210 to form an isolation opening 262, as shown in FIGS. 7A-7B. FIG. 7A is a cross-sectional view of the semiconductor device 200 along the x-direction. FIG. 7B is a schematic cross-sectional view of the semiconductor device 200 along the y-direction.

In some embodiments, the etch process can be achieved through HBr based plasma etch. In some embodiments, O₂ or CO₂ may be added to HBr. In some embodiments, the plasma etch process may be high density plasma process. The etch process may be performed using processing chambers with an ICP (inductive coupled plasma) or dipole antenna plasma source. The plasma may be driven by an RF power generator using AC electrical current operating on a frequency of multiple of 13.56 MHz and 27 MHz. The process chamber may be operated at a pressure in a range of about 2 mTorr to about 150 mTorr. The etch process may be performed at a temperature range between about 20 degrees Celsius to about 120 degrees Celsius. The RF power generator may be operated at a power level between about 100 W to about 2500 W. In some etching operations, the etch plasma may be pulsed with a duty cycle in a range of about 5% to 95%. In some embodiments, an RF bias power may be applied to a substrate pedestal in the process chamber. The RF bias power may be in a range of about 0 W to about 2500 W. In some embodiments, the plasma operation may be performed with only bias power, i.e., with zero plasma power, to enhance etch directionality.

In some embodiments, the etch process may be performed in a plasma etch chamber with in-situ ALD capability so that a passivation layer with sufficient protection may be formed in a subsequent operation, i.e. operation 118.

In some embodiments, the etch process in operation 116 may be performed continuously to achieve a rapid etching rate. After operation 116, an opening 260 is formed. In some embodiments, the opening 260 may have a first depth D₂₆₀, which is defined by a distance between the top most semiconductor channel layer 216 and a bottom 260b of the opening 260. The depth D₂₆₀ may be selected according to desireable level of the narrowest CD. In some embodiments, the bottom 260b of the opening 260 is below a top surface 212f of the well portion 212 of the substrate 210. In some embodiments, the depth D₂₆₀ is in a range between about 30 nm and about 100 nm. In some embodiments, a ratio of the depth D₂₆₀ over the stack height H₂₂₀ of the semiconductor fins 220 may be in a range between about 1.1 and 1.5.

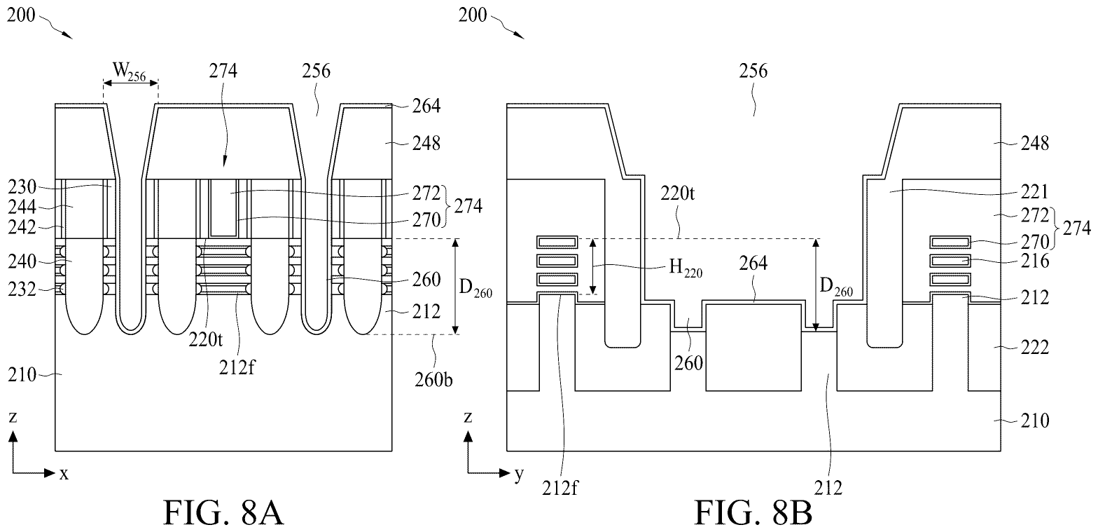

In operation 118, an enhanced passivation layer 264 are formed in the openings 260, as shown in FIGS. 8A-8B. FIG. 8A is a cross-sectional view of the semiconductor device 200 along the x-direction. FIG. 8B is a schematic cross-sectional view of the semiconductor device 200 along the y-direction.

According to embodiments of the present disclosure, the enhanced passivation layer 264 has increased etching resistivity against etching chemistry used for subsequent semiconductor etching, such as the etching chemistry used in the operation 116. The enhanced passivation layer 264 may include one or more dielectric material having etching resistivity against semiconductor etching chemistry, such as the etching chemistry used in the operation 116. In some embodiments, the enhanced passivation layer 264 may be a dielectric material, such as SiO, SiNO, SiN, or the similar. In some embodiments, the enhanced passivation layer 264 may be formed using precursors containing SiCl₄, O₂, and HBr. In some embodiments, the enhanced passivation layer 264 may contain impurities from the precursors, such as Br and H. In some embodiments, the enhanced passivation layer 264 may be Br containining SiO formed using SiCl4/HBr and O₂/SO₂/CO₂ precursors.

In some embodiments, the enhanced passivation layer 264 is deposited by an ALD process in the same chamber as the etch process performed in operation 116. In some embodiments, the enhanced passivation layer 264 may be formed using an in-situ ALD technique in and etching chamber. For example, an in-site ALD technique using precussors such as DIPAS (diisopropylaminosilane) and BTBAS (bis (tertiary-butylamino) silane) in combination with Ar or O2 plasma treatment are used to form silicon containing film. For example, the enhanced passivation layer 264 may be formed by supplying a silicon source gas, such as DIPAS or BTBAS to the process chamber, supplying a plasma of a reactive gas, such as oxygen or a nitrogen containing gas, to the process chamber. The radicals from the plasma of the reactive gas oxidize or nitride substances derived from the silicon source to form the silicon-containing passivation film.

The etching resistivity of the enhanced passivation layer 264 may be increased by increasing the thickness, density, changing the composition of the precursor, or a combination. In some embodiments, the enhanced passivation layer 264 is formed by increasing deposition time to achieve increased thickness. In some embodiments, the enhanced passivation layer 264 may have a thickness between about 0.5 nm and about 5 nm. In some embodiments, the enhanced passivation layer 264 may be formed with enhanced plasma dissociation to achieve greater density. In some embodiments, the enhanced passivation layer 264 may be a silicon oxide having a density in a range between about 2.648 g/cm³ and about 4.0 g/cm³. In some embodiments, the enhanced passivation layer 264 may be formed using precursors containing higher concentration of nitrogen.

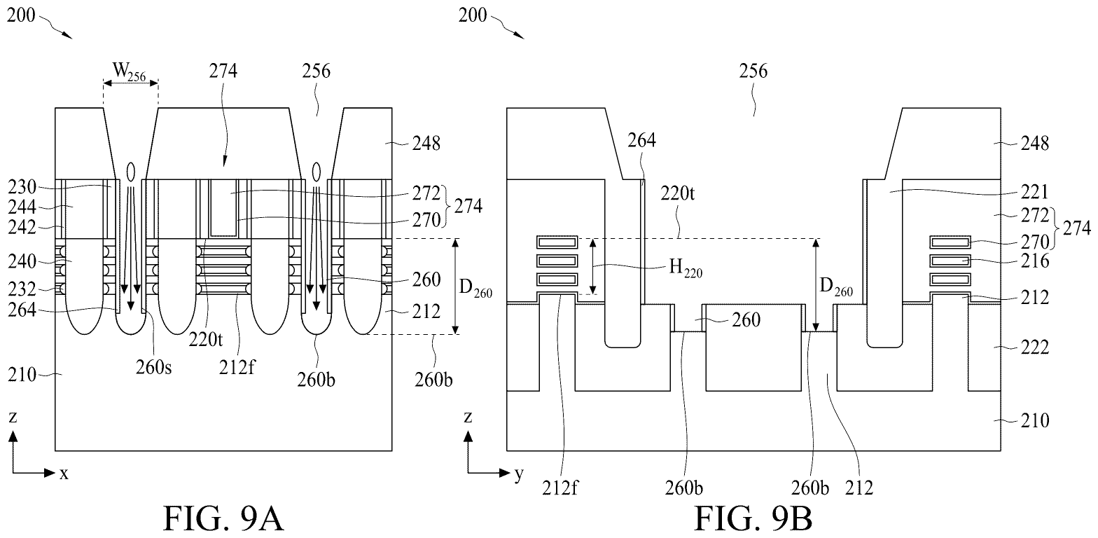

In operation 120, a directional break-through operation is performed to remove the enhanced passivation layer 264 from the bottom 260b of the opening 260, as shown in FIGS. 9A-9B. FIG. 9A is a cross-sectional view of the semiconductor device 200 along the x-direction. FIG. 9B is a schematic cross-sectional view of the semiconductor device 200 along the y-direction. As shown in FIG. 9A, processing gases are biased vertically towards the bottom 260b of the openings 260.

In some embodiments, the break-through operation may be an etch process based on a fluorine containing etchant, such as CF₄, CHF₃, CH₂F₂, CHF₃, C₄F₆, or a combination thereof. In some embodiments, when the enhanced passivation layer 264 includes Br containing SiO, low selective etchants, such as CF₄/C₄F₆/CHF₃, are used in a high directional break through operation to remove the enhanced passivation layer 264 from the bottom 260b of the opening 260. After the break-through operation, the enhanced passivation layer 264 is removed from the bottom 260b of the opening 260, and remain on sidewalls 260s of the opening 260. As shown in FIGS. 9A-9B, after the operation 120, the enhanced passivation layer 264 only remains on the vertical surfaces, and is removed from other horizontal and sloped surfaces, such as the top of the horizontal and sloped surfaces of the mask layer 248.

In some embodiments, the break-through process is performed in the same chamber as deposition process in operation 118, and the etch process performed in operation 116.

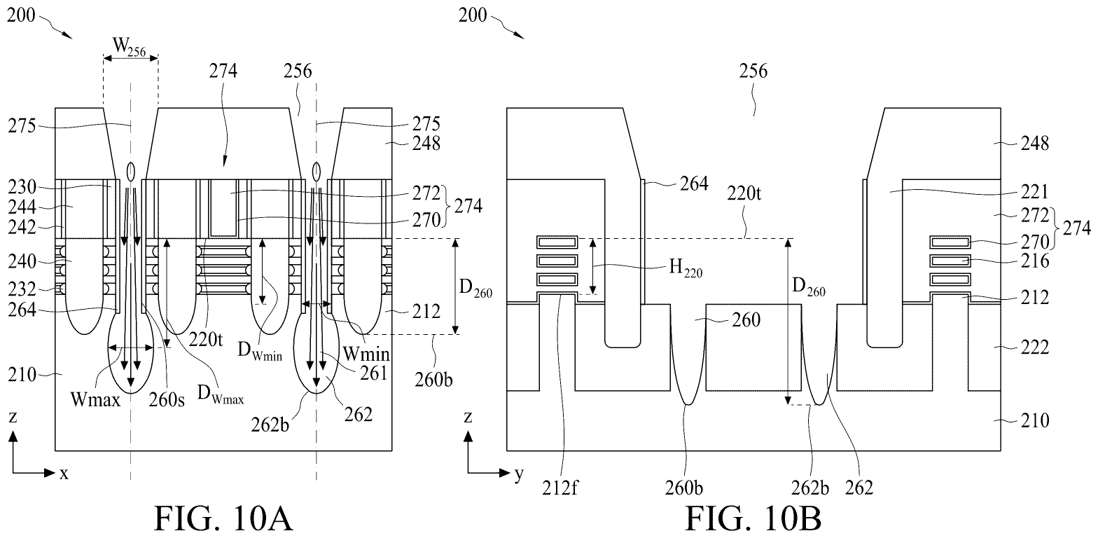

In operation 122, a second semiconductor etch process is performed to etch the substrate 210 below the enhanced passivation layer 264 forming an opening 262, as shown in FIGS. 10A-10B. FIG. 10A is a cross-sectional view of the semiconductor device 200 along the x-direction. FIG. 10B is a schematic cross-sectional view of the semiconductor device 200 along the y-direction.

In some embodiments, the second etch process may be performed using an etch chemistry similar to the first etch process in operation 116. The etch process can be achieved through HBr based plasma etch. In some embodiments, O₂ or CO₂ may be added to HBr. In some embodiments, the plasma etch process may be high density plasma process in condition similar to the etch process in operation 116. In some embodiments, the second etch process is performed to form the opening 262 in the semiconductor substrate 210 below the enhanced passivation layer 264. A bottom 262b of the opening 262 may have a depth D₂₆₂ from the top most semiconductor channel layer 216. The depth D₂₆₂ may be determined according to device design. For example the depth D₂₆₂ is selected to break electrical connection between the source/drain regions 240 through the semiconductor substrate 210. In some embodiment, the depth D₂₆₂ may be in a range between about 100 nm and about 200 nm.

As shown in FIG. 10A, the enhanced passivation layer 264 reduces the diameter of the opening 260, particularly, the diameter of the opening 260 at the level of the semiconductor channel layers 216. In the situation when the EPI CD, or spacing between the source/drain regions 240, is small, the diameter of the opening 260 is further reduced, forming a choke for fluid flow 261 of etchant in operation 122. After passiving the choke, the fluid flow 261 of etchant fans out to a wider angle, resulting in a large diameter of the opening 262. As shown in FIG. 10A, the opening 262 is wider along the x-direction than the opening 260. The combined openings 260, 262 may have a maximum width Wₘₐₓ at a depth D_{Wmax} from a fin top 220t or the topmost semiconductor channel layer 216, and a minimum width Wₘᵢₙ at a depth D_{Wmin} from the fin top 220t or the topmost semiconductor channel layer 216. In some embodiments, the depth D_{Wmax} of maximum width or bowing width is below the first depth D260 and above the second depth D262. The depth D_{Wmin} of the minimum width or necking width is above the first depth D260. Particularly, the minimum width Wₘᵢₙ is located below the fin top 220t or the topmost semiconductor channel layer 216 and above the first depth D260. In some embodiments, the depth D_{Wmin} is located below all the semiconductor channel layers 216. When the first depth D260 is below the lower most semiconductor channel layer 216 or below the source/drain regions 240, formation of the openings 260, 262 is unlikely to damage the epitaxial source/drain regions 240.

In some embodiments, the maximum width Wₘₐₓ is in a range between about 15 nm and 50 nm. In some embodiments, a ratio of the maximum width Wₘₐₓ over the EPI CD may be in a range between about 0.8 and 2.0. In some embodiments, the depth D_{Wmax} is in a range between about 30 nm and about 100 nm. In some embodiments, a ratio of the depth D_{Wmax} over the stack height H₂₂₀ of the semiconductor fins 220 may be in a range between about 1.2 and 2.0.

In some embodiments, the minimum width Wₘᵢₙ is in a range between about 10 nm and 30 nm. In some embodiments, a ratio of the minimum width Wₘᵢₙ over the EPI CD may be in a range between about 0.5 and 0.8. In some embodiments, the depth D_{Wmin} is in a range between about 10 nm and about 50 nm. In some embodiments, a ratio of the depth D_{Wmin} over the stack height H₂₂₀ of the semiconductor fins 220 may be in a range between about 0.5 and 1.1.

Additionally, as shown in FIG. 10A, the opening 262 is also substantially symmetrical. Not mean to be bonded by theory, the choke of the fluid flow 261 during the etch operation 122 causes the fluid flow 261 exiting the opening 260 to be substantially symmetrical to a central axis of the opening 260, resulting in a substantially symmetrical opening 262. In some embodiments, the openings 262 may be substantially symmetrical about a central axis 275 of the gate structures 274. As discussed later, the etching processes in operations 116, 118, 120, 122 may be used to correct pattern overlay shift in the mask layer 248.

As shown in FIGS. 10A-10B, the enhanced passivation layer 264 may remain on the vertical sidewalls of the openings 256 during and after the second etching process protecting the adjacent source/drain regions 240.

In some embodiments, the second etch process is performed in the same chamber as the break-through process in operation 120, deposition process in operation 118, and the etch process performed in operation 116.

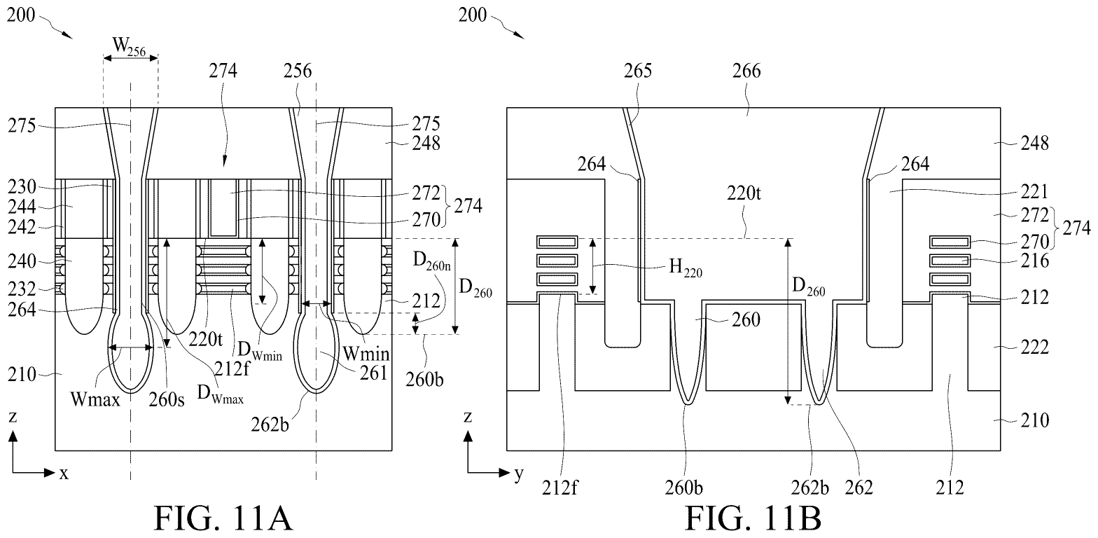

In operation 124, the openings 260 and 262 are filled with isolation material to form isolation structures 266, as shown in FIGS. 11A-11B. FIG. 11A is a cross-sectional view of the semiconductor device 200 along the x-direction. FIG. 11B is a schematic cross-sectional view of the semiconductor device 200 along the y-direction.

Prior to filling the openings 260, 262, a pre-cleaning process may be performed. During the pre-cleaning process, all or a portion of the enhanced passivation layer 264 may be removed. In some embodiments, a thin film of the enhance passiviation layer 264 may remain on sidewalls 260s of the openings 260 prior to the dielectric fill operation.

In some embodiments, a fill material is deposited in the openings 260, 262 in place of the removed semiconductor substrate 210, the semiconductor fins 220, and the section of the replacement gate structure 274. The fill material may be an insulating material. In some examples, the fill material may be a single insulating material, and in other examples, the fill material may include multiple different insulating materials, such as in a multi-layered configuration. The fill material may include or be silicon oxide, silicon nitride, silicon oxynitride, silicon carbide, silicon carbon nitride, the like, or a combination thereof, and may be deposited by CVD, PVD, ALD, or another deposition technique. In some embodiments, a liner layer 265 may be formed prior to depositing the fill material. After depositing the liner layer 265 and the fill material, a CMP process may be performed to expose the sacrificial gate structures 228 for subsequent processes. In some embodiments, the enhanced passivation layer 264 may be disposed around an upper portion of the isolation structure 266.

The isolation structure 266 extends sufficiently deep into the semiconductor substrate 210 and provides electrical isolation between the source/drain regions 240 at opposing sides.

The etching, passivation and etching process according to the present disclosure, e.g. as described in operations 116, 118, 120, 122, may be used to form a high aspect ratio trench, such as CMODE and CPODE, without damaging nearby features. In the first etching process, as described in operation 116, the trench is etch to a first depth, e.g. the depth D₂₆₀. The first depth may be selected according to desirable location of the minimum width or necking width, such as the minimum width Wmin in FIG. 10A. In some embodiments, a necking depth 260n, corresponding to the location of the opening 260 with the minimum width Wₘᵢₙ, is above the bottom 260b of the opening 260. In some embodiments, a necking distance D₂₆₀ₙ, which refers to the distance between the bottom 260b and the necking depth 260n, is in a range between about 0 nm and about 10 nm.

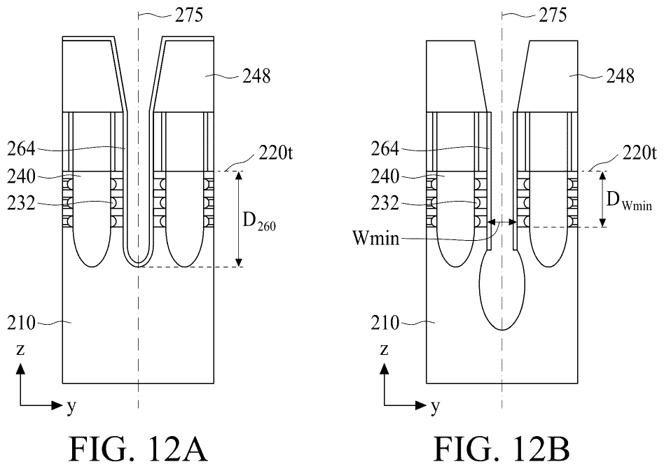

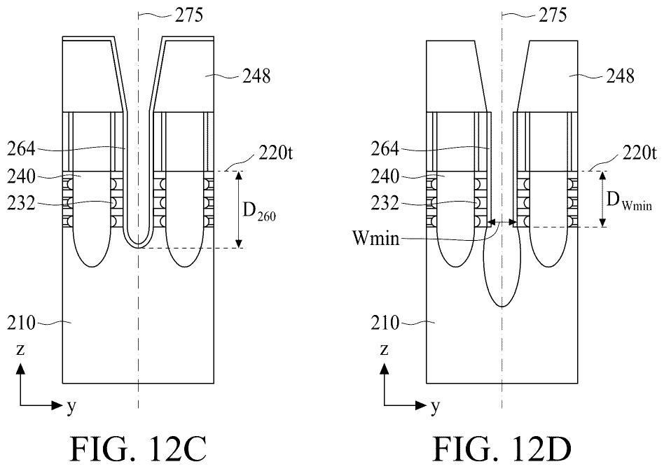

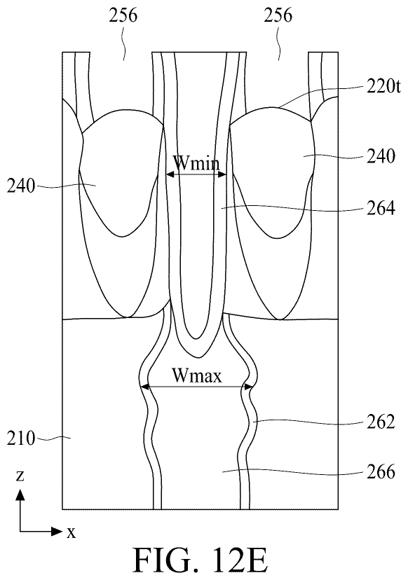

FIG. 12A-12B are partial sectional views of the semiconductor device 200 after the operation 116 and 122 in one example. FIG. 12C-12D are partial sectional views of the semiconductor device 200 after the operation 116 and 122 in one example. A longer etching step in operation 116 results in a lower first depth as shown in FIG. 12A and lower depth D_{Wmin} as shown in FIG. 12B. A shorter etching step in operation 116 results in a higher first depth as shown in FIG. 12C and a higher depth D_{Wmin} as shown in FIG. 12D. For a CMODE or CPODE process, it is desirable to have the minimum width or necking width at the level of the epitaxial source/drain regions while the maxium width or bowing width positioned below the epitaxial source/drain regions.

FIG. 12E is a schematic cross-sectional view of an example device according to the present disclosure. In the device of FIG. 12E, the isolation structures 266 is formed between two epitaxial source/drain regions 240 and into the substrate 210. The minimum width Wₘᵢₙ of the isolation structure 266 located at the level between the epitaxial source/drain regions 240 and the maximum width Wmax of the isolation structure 266 is at the level below the source/drain regions 240. The maxium width Wmax is greater than the spacing between the epitaxial source/drain regions 240. The enhanced passivation layer 264 is located on sidewalls of the isolation structure 266 and above the maximum width Wmax.

Even though, the semiconductor device 200 described above is a GAA device, the method 100 may be used to fabricate FinFET devices as well. The method 100 may be used to fabricate semiconductor devices with various designs, such as dummy fins.

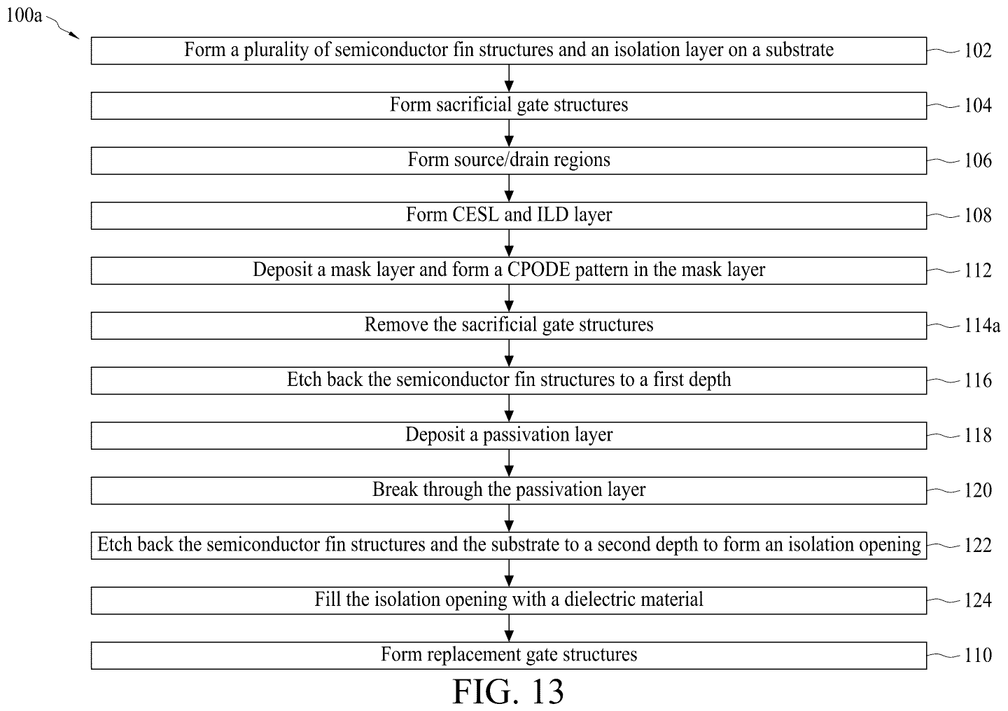

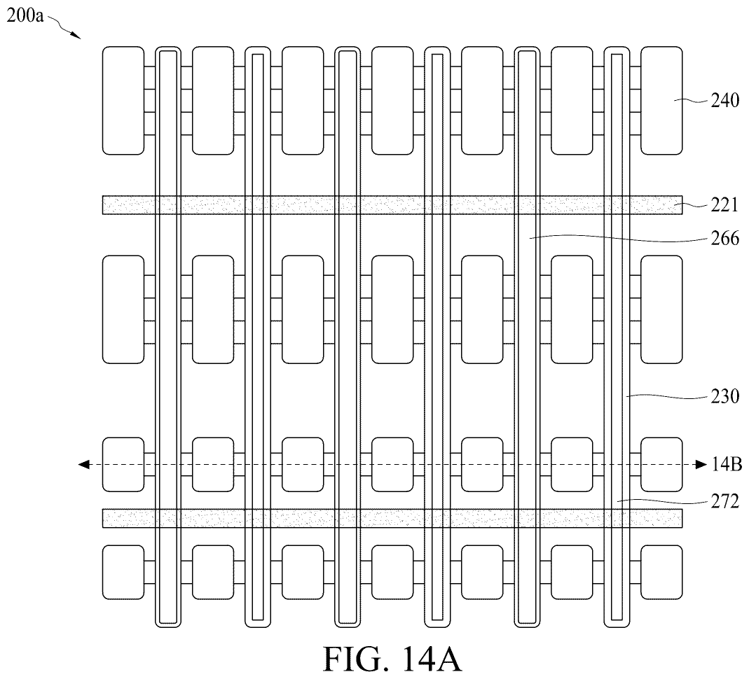

The etch-passivation-etch process according to the present disclosure may also be used to form isolation structures in a CPODE process. FIG. 13 is a flow chart of a method 100a for manufacturing of a semiconductor substrate according to embodiments of the present disclosure. The method 100a relates to forming isolation structures using CPODE process. The method 100a is similar to the method 100 except that a replacement gate process is performed after the CPODE process. Particularly, in the method 100a, the operation of forming replacement gate structures (operation 110) is performed after formation of the isolation structures (operations 116, 118, 120, 122, 124).

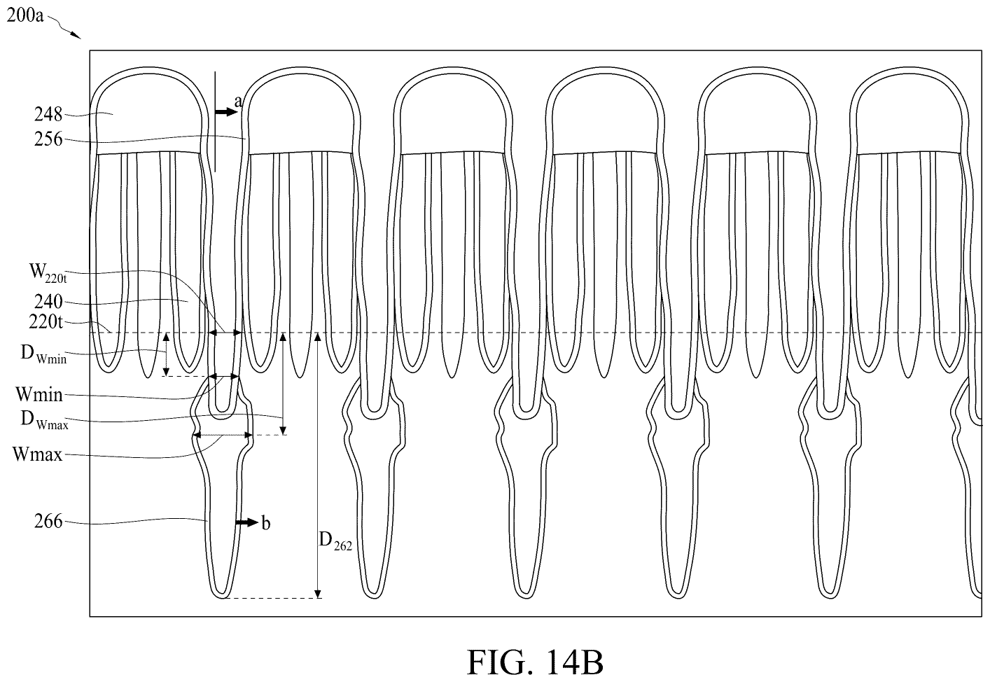

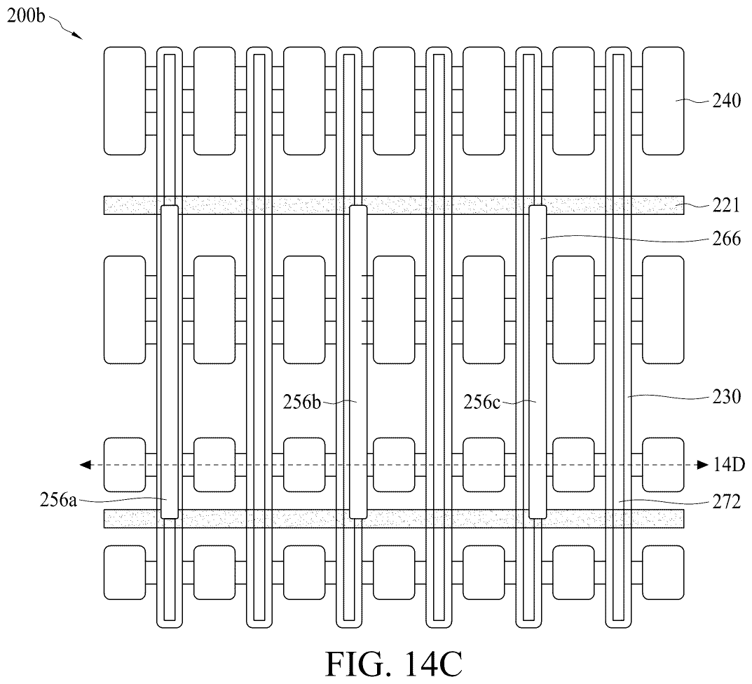

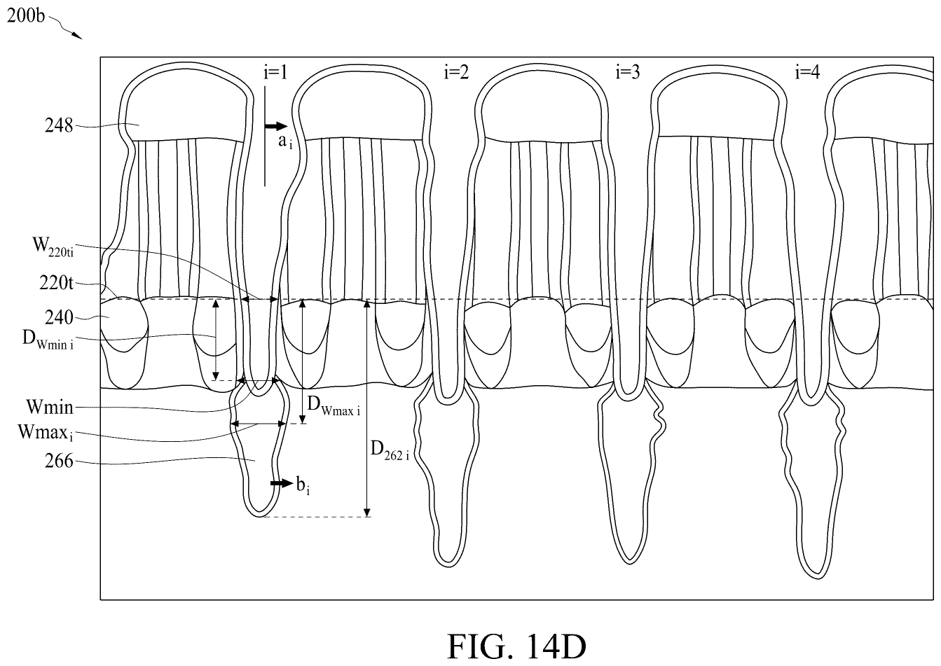

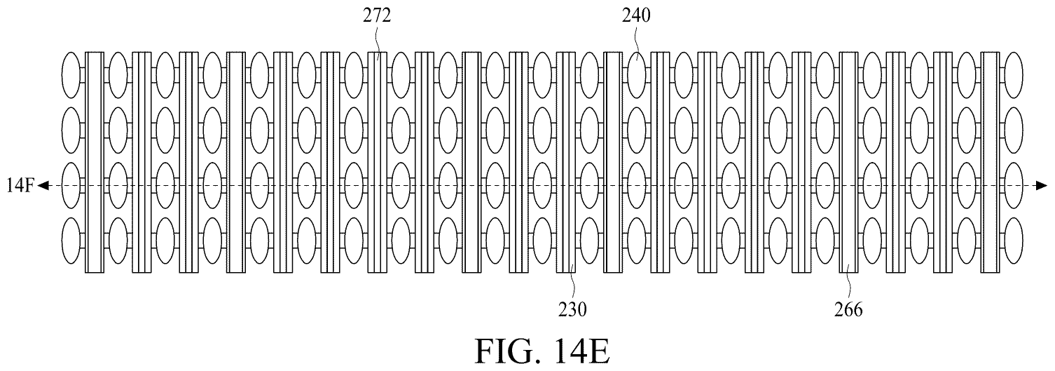

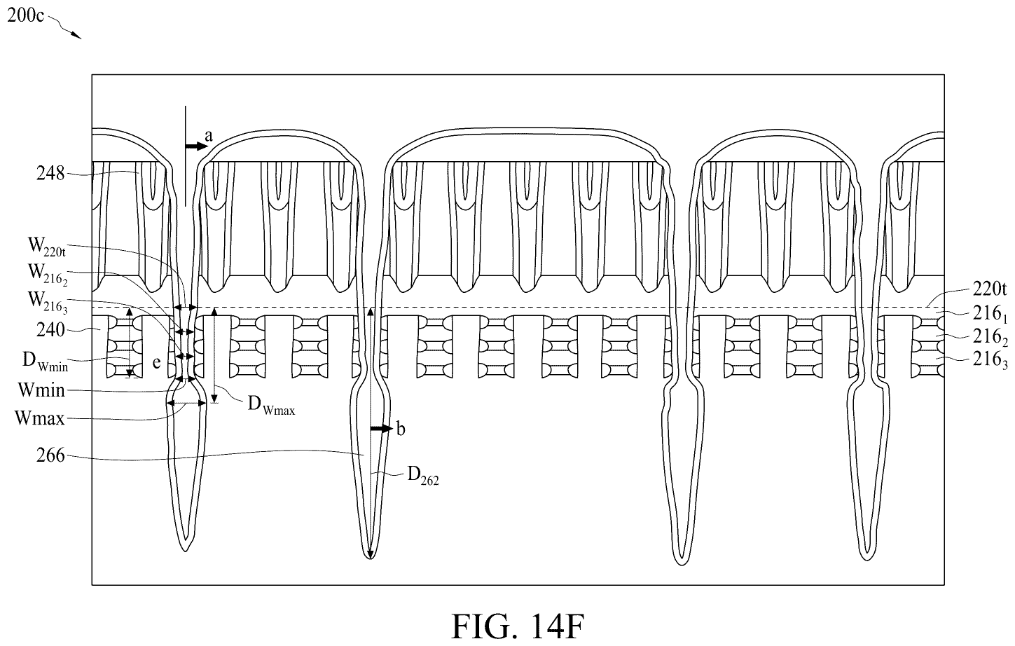

An overlay shift may be inherent during patterning process due to limitation of the fabrication equipment. In some situations, an overlay shift may be intentionally added in certain patterns to avoid photoresist peeling. However, an overlay shift may degrade device performance and/or cause reliability issues. As feature size decreases, overlay shift has a more significant impact on device performance. During CMODE/CPODE, overlay shift between the openings in the mask layer, such as the opening 256 in the mask layer 248, and gale structures may result in the further shift in the isolation openings or non-symmetrical isolation openings. As discussed above, the etching, passivation, and etching process according to the present disclosure may be used to reduce pattern overlay shift impact on the symmetry of etch profile in horizontal direction. By employing sufficient passivation during the etch process, the CD in horizontal direction could be conserved, minimizing the EPI damage risk due to the overlay shift of CPODE patterns. FIGS. 14A-14E schematically demonstrate various examples of semiconductor devices according to embodiments of the present disclosure.

FIG. 14A is a schematic layout view of a semiconductor device 200a. As shown in FIG. 14A, the semiconductor device 200a includes isolation structrures 266 formed in every other gate structures 272. FIG. 14B is a schematic cross sectional view of the semiconductor device 200a along line 14B in FIG. 14A.

As shown in FIG. 14B, the isolation structures 266 are formed according to the method 100 or 100a. The isolation structures 266 are formed by etching through openings 256 in the mask layer 248 using the etching scheme described in operations 116, 118, 120, 122 above. In the semiconductor device 200a, the average width W220t at the fin top 220t is about 17.7 nm, the minimum width Wmin or the necking width is about 17.4 nm, and the maximum width Wmax or the bowing width is about 30.3 nm. The isolation structures 266 has an average depth D₂₆₂ from the fin top 220t is about 156.8 nm, the average necking depth D_{Wmin} is 39.0 nm, and the average bowing depth D_{Wmax} is 61.4 nm. The openings 256 have an average overlay shift, at level a, for about −0.2 nm while the horizontal bowing position shift, at level b, for about −0.4 nm.

FIG. 14C is a schematic layout view of a semiconductor device 200b. As shown in FIG. 14C, the semiconductor device 200b includes isolation structrures 266 formed in every other gate structures 272. FIG. 14D is a schematic cross sectional view of the semiconductor device 200b along line 14D in FIG. 14C.

As shown in FIG. 14D, the isolation structures 266 are formed according to the method 100 or 100a. The isolation structures 266 may be formed by etching through 256a, 256b, 256c in the mask layer 248 using the etching scheme described in operations 116, 118, 120, 122 above. During patterning, overlay shift is intentionally introduced to the openings 256b, 256c to avoid PR peeling. In the semiconductor device 200b, the average width W220t at the fin top 220t is about 17.7 nm, the minimum width Wmin or the necking width is about 17.7 nm, and the maximum width Wmax or the bowing width is about 28.3 nm. The isolation structures 266 has an average depth D₂₆₂ from the fin top 220t is about 152.8 nm, the average necking depth D_{Wmin} is 51.4 nm, and the average bowing depth D_{Wmax} is 70.5 nm. The openings 256 have an average overlay shift, at level a, for about −3.9 nm while the horizontal bowing position shift, at level b, for about −0.7 nm. The semiconductor device 200b shows the method of present disclosure reduces overlay shift in the isolation structures 266.

FIG. 14E is a schematic layout view of a semiconductor device 200c. As shown in FIG. 14E, the semiconductor device 200c includes isolation structures 266 formed in every other gate structures 272. FIG. 14E is a schematic cross sectional view of the semiconductor device 200c along line 14E in FIG. 14F.

As shown in FIG. 14F, the isolation structures 266 are formed according to the method 100 or 100a. The isolation structures 266 are fromed by etching through openings 256 in the mask layer 248 using the etching scheme described in operations 116, 118, 120, 122 above. The semiconductor device 200c is a GAA device having three semiconductor layers 216₁, 216₂, 216₃. In the semiconductor device 200c, the average width W220t at the fin top 220t is about 17.9 nm, average width W216₂ at the second semiconductor channel layer 216₂, is about 16.6 nm, average width W216₃ at the second semiconductor channel layer 216₃, is about 16.9 nm, the minimum width Wmin or the necking width is about 16.1 nm, and the maximum width Wmax or the bowing width is about 31.0 nm. The isolation structures 266 has an average depth D₂₆₂ from the fin top 220t is about 182.6 nm, the average necking depth D_{Wmin} is 50.9 nm, and the average bowing depth D_{Wmax} is 68.2 nm. The necking depth D_{Wmin} is below the bottom most semiconductor channel layer 216. The openings 256 have an average overlay shift, at level a, for about −0.2 nm while the horizontal bowing position shift, at level b, for about −0.4 nm.

Various embodiments or examples described herein offer multiple advantages over the state-of-art technology. The methods according to the present disclosure enables gate pitch scaling in CPODE or CMODE process without damaging the epitaxial source/drain regions.

It will be understood that not all advantages have been necessarily discussed herein, no particular advantage is required for all embodiments or examples, and other embodiments or examples may offer different advantages.

Some embodiments of the present provide a method. The method comprises forming a fin structure on a substrate along a first direction, a gate structure across the fin structure, and source/drain regions on opposite sides of the gate structure; depositing a mask layer over the gate structure; forming a pattern in the mask layer, wherein the pattern comprises an elongated opening formed over a portion of the gate structure; and etching the gate structure through the elongated opening to expose the fin structure; etching the fin structure to a first depth; depositing an enhanced passivation layer; performing a break-through etch process; and etching the fin structure and the substrate to a second depth to form an isolation opening; and filling the isolation opening with a dielectric material.

Some embodiments of the present provide a semiconductor device. The semiconductor device comprises a semiconductor substrate; a fin structure on the semiconductor substrate and extending along a first direction; a gate structure disposed across the fin structure and extending along a second direction; a first source/drain region and a second source/drain region formed on the fin structure and on opposite sides of the gate structure; and an isolation structure disposed in the gate structure, wherein the isolation structure extends from a top surface of the fin structure into the semiconductor substrate, the isolation structure has a maximum width at a first level below the first and second source/drain regions, and a necking width at a second level between the first level and the top surface of the fin structure.

Some embodiments provide a method for forming a semiconductor device. The method comprises forming a fin structure on a substrate along a first direction, and a first gate structure and a second gate structure across the fin structure; depositing a mask layer over the first and second gate structures; forming a pattern in the mask layer, wherein the pattern comprises: a first elongated opening formed over and parallel to the first gate structure, wherein the first elongated opening is shifted from the first gate structure for a first overlay shift; and a second elongated opening formed over and parallel to the second gate structure; etching through the first and second elongated openings in the mask layer to form a first isolation opening and a second isolation opening in the substrate, wherein the first isolation opening is substantially aligned with the first gate structure; and depositing a dielectric layer to fill the first isolation opening and the second isolation opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a fin structure on a substrate along a first direction, a gate structure across the fin structure, and source/drain regions on opposite sides of the gate structure;
depositing a mask layer over the gate structure;
forming a pattern in the mask layer, wherein the pattern comprises an elongated opening formed over a portion of the gate structure; and
etching the gate structure through the elongated opening to expose the fin structure;
etching the fin structure to a first depth;
depositing an enhanced passivation layer;
performing a break-through etch process; and
etching the fin structure and the substrate to a second depth to form an isolation opening; and
filling the isolation opening with a dielectric material.

2. The method of claim 1, wherein etching the fin structure to a first depth is performed continuously.

3. The method of claim 2, wherein the first depth is below the source/drain regions.

4. The method of claim 1, wherein depositing the enhanced passivation layer comprises performing an atomic layer deposition process.

5. The method of claim 4, wherein etching the fin structure to a first depth, depositing the enhanced passiviation layer, performing a break through etch process, and etching the fin structure and the substrate to a second depth are performed in the same chamber.

6. The method of claim 1, wherein the isolation opening has a maximum width between the first depth and second depth.

7. The method of claim 6, wherein the isolation opening has a minimum width above the first depth.

8. A semiconductor device, comprising:
a semiconductor substrate;
a fin structure on the semiconductor substrate and extending along a first direction;
a gate structure disposed across the fin structure and extending along a second direction;
a first source/drain region and a second source/drain region formed on the fin structure and on opposite sides of the gate structure; and
an isolation structure disposed in the gate structure, wherein the isolation structure extends from a top surface of the fin structure into the semiconductor substrate, the isolation structure has a maximum width at a first level below the first and second source/drain regions, and a necking width at a second level between the first level and the top surface of the fin structure.

9. The semiconductor device of claim 8, wherein the maximum width is greater than a spacing between the first and second source/drain regions.

10. The semiconductor device of claim 8, further comprising a passivation layer disposed on sidewalls of the isolation structure, wherein the passivation layer is disposed above the first level.

11. The semiconductor device of claim 10, wherein the passivation layer includes a Br containing silicon oxide.

12. The semiconductor device of claim 8, wherein a ratio of the maximum width over a necking width is in a range between about 1.5 and about 2.0.

13. The semiconductor device of claim 8, wherein the fin structure comprises two or more semiconductor channel layers vertically stacked, and the second level is below a bottom most semiconductor channel layer.

14. The semiconductor device of claim 8, wherein the isolation structure has a first overlay shift relative to the gate structure above a top surface of the fin structure, and a second overlay shift relative to the gate structure at the first level.

15. The semiconductor device of claim 14, wherein the first overlay shift is greater than the second overlay shift.

16. A method comprising:
forming a fin structure on a substrate along a first direction, and a first gate structure and a second gate structure across the fin structure;
depositing a mask layer over the first and second gate structures;
forming a pattern in the mask layer, wherein the pattern comprises:
a first elongated opening formed over and parallel to the first gate structure, wherein the first elongated opening is shifted from the first gate structure for a first overlay shift; and
a second elongated opening formed over and parallel to the second gate structure;
etching through the first and second elongated openings in the mask layer to form a first isolation opening and a second isolation opening in the substrate, wherein the first isolation opening is substantially aligned with the first gate structure; and
depositing a dielectric layer to fill the first isolation opening and the second isolation opening.

17. The method of claim 16, wherein etching through the first and second elongated openings comprises:
etching the first gate structure and the second gate structure via the first and second enlongated openings to expose the fin structure; and
etching through fin structure and into the substrate via the first and second enlongated openings to form the first isolation opening and the second isolation opening in the substrate.

18. The method of claim 17, wherein etching through fin structure and into the substrate comprises:
etching the fin structure to a first depth;
depositing a passivation layer;
performing a breakthrough etch; and
etching the fin structure and the substrate to form the first and second isolation openings.

19. The method of claim 17, wherein the first depth is below a top surface of the substrate.

20. The method of claim 17, wherein the first isolation opening has a first width above the first depth and a second width below the first depth, and the second width is greater than the first width.
